(19) United States
(12) Patent Application Publication
(10) Pub. No.: US 2003/0172867 A1
(43) Pub. Date: Sep. 18, 2003

(54) Preparation of nano-sized crystals

(75) Inventors: Reuel Shinnar, Great Neck, NY (US); Alexander Couzis, New Windsor, NY (US); Charles Maldarelli, Wayne, NJ (US)

Correspondence Address: DARBY & DARBY P.C., 805 Third Avenue, New York, NY, 10022, US

(73) Assignee: NUCCON TECHNOLOGIES INC.

(21) Appl. No.: 10/336,664

(22) Filed: Jan. 3, 2003

Related U.S. Application Data
(60) Provisional application No. 60/346,020, filed on Jan. 4, 2002.

(51) Int. Cl. C30B 7/00; C30B 21/02; C30B 28/06

(52) U.S. Cl. 117/68

(57) ABSTRACT

A process for generating single crystalline nano-crystals is described. The nano-crystals are formed on a substrate containing nano-sectors having functional groups which promote nucleation of crystals and inert sectors which do not. The particle size of the crystals is controlled by the size of the nano-sectors and the crystals become reversibly attached to the surface of the nano-sectors during crystallization. In addition, the substrate containing the single crystalline nano-crystals and the single crystalline nano-crystals formed by the process are also claimed.

This application claims the priority of U.S. Provisional Application No. 60/346,020, filed on Jan. 4, 2002, which is hereby incorporated by reference in its entirety.

### BACKGROUND OF THE INVENTION

There is growing interest in producing via crystallization nano-particles with a controllable size and a very narrow size distribution. Such particles find use in numerous technological and scientific applications such as medicine, photonics, material science, and imaging.

Currently, mainstream methods for preparing nano-particles fall into one of six categories: (i) physical (see Kruis, F. E.; Fissan, H.; Peled, A. J. Aerosol Sci. 1998, 29, 511) and chemical vapor deposition (see Kruis, F. E.; Fissan, H.; Peled, A. J Aerosol Sci. 1998, 29, 511; and Hong, L. S.; Lai, H. T. Ind. Eng. Chem. Res. 1999, 38, 950) including aerosol implementations (see Rumminger, M. D.; Linteris, G. T. Combustion and Flame 2000, 123, 82-94; Loscertales, I. G. Journal of Aerosol Science 2000, 31, 923-932; Houriet, R.; Vacassy, R.; Hofmann, H. Nanostructured Materials 1999,11, 1155-1163; Gonzalez-Carreno, T.; Morales, M. P.; Sema, C. J. Materials Letters 2000,43,97-101; Kruis, F. E.; Fissan, H.; Rellinghaus, B. Materials Science and Engineering B-Solid State Materials For Advanced Technology 2000, 69, 329-334; Makino, T.; Suzuki, N.; Yamada, Y.; Yoshida, T.; Seto, T.; Aya, N. Applied Physics a-Materials Science & Processing 1999, 69, S243-S247; and Magnusson, M. H.; Deppert, K.; Malm, J. O.; Bovin, J. O.; Samuelson, L. Nanostructured Materials 1999, 12, 45-48), (ii) precipitation methods such as sol-gel (see Chatterjee, A.; Chakravorty, D. J Mater. Sci. 1992,27,4115) and reactive precipitation (see Gu, Y. F.; Wang, S.; Hu, L. M.; Zhang, A. I. J. East China Inst. Chem. Technol. 1993, 15, 550; and Jiang, A. Q.; Li, G. H.; Zhang, L. D. J. AppL Phys. 1998, 83, 4878), (iii) synthesis in microemulsions (see Kim, D. W.; Oh, S. G.; Lee, J. D. Langmuir 1999, 15, 1599-1603; Bandyopadhyaya, R.; Kumar, R.; Gandhi, K. S. Langmuir 2000, 16, 7139-7149; Debuigne, F.; Jeunieau, L.; Wiame, M.; Nagy, J. B. Langmuir 2000, 16, 7605-7611; Lade, M.; Mays, H.; Schmidt, J.; Willumeit, R.; Schomacker, R. Colloids and Surfaces a-Physicochemical and Engineering Aspects 2000, 163, 3-15; and Lopez Perez, J. A.; Lopez Quintela, M. A.; Mira, J. J. Phys. Chem. B 1997, 101, 8045), (iv) sonochemical processing, (see Mizukoshi, Y.; Okitsu, K.; Maeda, Y. J. Phys. Chem. B 1997, 101, 7033), (v) supercritical processing (see Reverchon, E.; Della Porta, C.; Di Trolio, A.; Pace, S. Industrial & Engineering Chemistry Research 1998, 37, 952-958; and Reverchon, E.; Della Porta, G. Powder Technology 1999, 106, 23-29), and (vi) high energy ball milling. Chemical and physical vapor deposition are somewhat limiting because they require expensive equipment, ultra low pressures, and typically only work with materials that have relatively high vapor pressures (see Hong, L. S.; Lai, H. T. Ind. Eng.Chem. Res. 1999, 38, 950). High energy ball milling physically grinds the particles down to a high surface area fonn. Such techniques work mainly with materials that are hard, fracture easily, and are thermally stable, because milling will cause local surface heating that can result in phase transitions of the material. However, milling is not useful with a number of materials that are soft, or have low melting point, such as organic molecular crystals. Furthermore, local heating due to the high shear of the milling can cause either melting or annealing to a different crystalline state. Similarly, aerosol methods are not useful with certain organic materials because such materials are not stable at the high temperatures required by these processes.

Microemulsion and sol-gel techniques are based on crystallization but suffer from large variances in the particle size distribution that is not desirable for many purposes. This large variance is caused because small particles adhere to each via Van der Waals forces as a result of their large area-to-volume ratio. Furthermore, in a crystallizing solution, the supersaturated solution has the tendency to create bridges between the particles. Because of these factors that lead to size coarsening, it is hard to design particles with a specific size and size distribution. It is also hard with the latter two processes to, a priori, design them for a specific particle in the narrow range.

### BRIEF SUMMARY OF THE INVENTION

In accordance with the invention, a unique method has been discovered to form crystalline particles in a range of from 5 to 1000 nanometers with a very small size variance and free of larger particles.

A suitable solid surface of a planar or particulate carrier is covered by a patterned thin monomolecular layer of self-assembling surfactants or polymers. These self-assembling moieties comprise three regions: (i) an anchoring functionality that allows the irreversible covalent bonding of the surfactant or polymer onto the appropriate substrate; (ii) a linker domain that controls the lateral interaction of the surfactant in the monolayer; and (iii) a terminal functionality that is displayed to the environment. The patterned layer that covers the planar or particulate carrier is comprised of self-assembling surfactants or polymers with similar anchoring functionalities, and potentially varying linker and terminal functionalities, so that the minor phase (nano-sectors) of one terminal functionality are formed inside a major matrix phase (inert sectors) of another terminal chemical functionality. The surface of the substrate is substantially covered with nano-sectors bound by inert sectors, wherein the nano-sectors are either below the surface (nano-wells, see FIG. 1), co-planar (nano-domains, such as islands of 11-carboxyundecyltrimethoxysilanes in a matrix of undecyltrimethoxysilane, see FIG. 2), or elevated (nano-islands, such as islands of 11-carboxyundecyltrimethoxysilanes in a matrix of hexyltrichlorosilane, see FIG. 3) relative to the matrix inert sectors in these multicomponent layers.

The chemical terminal functionality matrix area is selected so that it is totally inert in the sense that it does not promote nucleation of the material to be crystallized, nor has any other effect on the crystallization process. Crystal templating is only promoted in the confines of the patterned nano-sectors. Furthermore, the nano templating areas (nano-sectors) have a controllable relatively uniform size in the nano range (5 to 1000 nanometers). The nano-sectors may be present in one of three distinct types as illustrated in FIGS. 1, 2 and 3.

Because these templates reduce the activation energy for nucleation, one can form nuclei on the templated domain from a metastable solution in which the super saturation is high enough to promote crystal growth but low enough to prevent self nucleation (homogeneous nucleation) inside the solution. Thus one can cover the whole area of the template with nuclei, which will then grow perpendicular to the surface. Even if there are several nuclei inside that nano template, the growth will form bridges and result in a single crystalline nano-particle in each nano-templating area. Because growth in the direction parallel to the substrate is confined by the templating domains and crystallization in the direction perpendicular to the substrate is relatively slow due to mass transfer limitations, the size of the nano-particle will be practically controlled by the size of the nano template. As there are available methods to create a large number of templating domains of relatively high density (10-50% of the area) with narrow size distribution, this allows one to crystallize very uniform crystalline nano-particles. Furthermore, by controlling the size of the templating domain, we can control, a priori, the size of the crystalline nano-particles, independent of the nature and properties of the compound to be crystallized as well as of the solvent used, a very important and unique feature of the invention.

Furthermore, as the crystalline particles remain attached to the surface, they do not interact with each other, thus preventing them from forming aggregates during the crystallization process. By keeping the longitudinal dimension of the growth slightly smaller than the templating domain diameter, it is ensured that no larger crystals are formed.

The basic concept of the invention is to form and grow the crystal within the confines of the templating nano-sectors (inside nano-wells, upon coplanar nano-domains or elevated nano-islands) on a specially treated surface, and keep them reversibly attached to the surface. This permits, at the end of the crystallization, any crystals formed in the solution to be rinsed off.

While the invention is not limited to any particular theory, it is believed that the lateral spread of the single crystalline nano-crystals is limited to the nano-sectors, i.e., those sectors containing functional groups (“the templates”) because only those surfaces have a low interfacial tension and can be wetted by the solute. The inert non-templating sectors, on the other hand, have high interfacial tension and therefore do not allow spreading.

By patterning the substrate surface so that the templates are bounded by the inert domains, the crystal growth is confined by the transition line that separates the two domains. For this reason, the templating domains may be recessed, co-planar or elevated, since the confinement is not purely physical.

Growing the nano-crystals attached to a surface during the whole crystallization process has several further unique advantages. Unlike other processes, the crystal can be cleaned, and if desired, coated with any desired coating. The crystal can then be removed from the surface by various means described herein, either into a stabilizing solution or into a solid matrix composed of particles. Since nano-particles are often used uniformly dispersed in a solid matrix, one can achieve a uniform dispersion by directly dislodging the nano-particles from the templating surface and directly dispersing them into the desired solid matrix dispersed in a liquid.

While these steps can be carried out in various ways, the subject invention relates specifically to the concept of growing the nano-crystals attached to the surface wherein the nano-crystals are confined to the area of uniformly sized nano-templating domains.

The subject invention has a further advantage in that it can simultaneously control crystal polymorph development. For example, while creating nano-crystals of a chiral drug, the method of the present invention can, with high selectivity, direct the crystallization to crystallize only one chiral isomer, thereby simultaneously separating the desired stereoisomer and forming nano-particles of a closely controlled particle size.

Another unique advantage of the invention is its ability to grow uniform-sized nano-particles by a reactive crystallization process. Reactive crystallization is very important for the formation of nano-particles of insoluble materials, e.g., iron oxide.

### BRIEF DESCRIPTION OF THE DRAWINGS

FIG. 1 is a simplified structure of a self-assembled monolayer with recessed nano-wells.

FIG. 2 is a simplified structure of a self-assembled monolayer with coplanar nano-domains.

FIG. 3 is a simplified structure of a self-assembled monolayer with elevated nano-islands.

FIG. 4 is a crystallization process flow chart.

FIG. 5a is an atomic force microscope image of amino terminated nano-islands before nucleation and growth of CdS.

FIG. 5b is an atomic force microscope image of amino terminated nano-islands after nucleation and growth of CdS.

FIG. 5c shows the particle size distribution of the CdS nano-crystals.

FIG. 6 is an illustration of vanillin nano-particles prepared in accordance with the invention.

### DETAILED DESCRIPTION OF THE INVENTION

The present invention is directed to the formation of nano-crystals in the range of 5-1000, preferably 5 to 400 nanometers, of uniform size and free of larger particles. In preparing these nano-crystals, initially, crystallization templates are created to clearly define nano-sized domains on an inert substrate surface. There are several methods available that may be used to make these templates:

(I) Microcontact Printing Soft Lithography: The microcontact printing (MCP) technique wherein self-assembled monolayers (SAMs) are used to chemically pattern micron and sub-micron sized features on surfaces (see Kumar, A.; Whitesides, G. M. Appl. Phys. Lett. 1993, 63, 2002-2004; Kumar, A.; Biebuyck, H. A.; Abbott, N. L.; Whitesides, G. M. J Am. Chem. Soc. 1992, 114, 9188-9189; and Xia, Y.; Qin, D.; Yin, Y. Current Opinion in Colloid & Interface Science 6 2001, 6, 54-64). The method involves first making a master of the desired pattern as a relief structure (a negative of the desired pattern) on a silicon surface. Most applications of MCP have used the microfabrication technique of photolithography to create the negative relief on the silicon master. This master is then used to fabricate polydimethylsiloxane (PDMS) elastomeric stamps by depositing and curing PDMS on the relief. The stamp is then inked with a solution containing the SAM to be deposited in the pattern (both thiol and silane surfactants have been used), and the inked stamp is then pressed for a short contact time on a surface (evaporated gold covered surfaces for the thiols and oxide surfaces for the silanes). Using electron beam fabricated masters, PDMS stamps have been made that faithfully produce the nanoscale pattern when inked with a SAM and contacted onto the surface. After the pattern has been created, the surrounding region can be backfilled with a second SAM to create a bifunctional surface.

(II) Direct Writing Photolithography Using SAMs as Resists: This technique uses silane SAMs as the resist to directly write the chemical pattern onto the surface (see Calvert, J. M.; Georger, J. H.; Peckerar, M. C.; Pehrsson, P. E.; Schnur, J. M.; Schoen, P. E. Thin Solid Films 1992, 210/211, 359-363; Dressick, W. J.; Calvert, J. M. Japanese Journal of Applied Physics 1993, 32, 5289-5839; and Dulcey, C. S.; Georger, J. H.; Krauthamer, V.; Stenger, D. A.; Fare, T. L.; Calvert, J. M. Science 1991, 252, 551-554).

In this technique, a homogeneous SAM of one chemical functionality is first deposited on a substrate. A mask is placed over the SAM, and the substrate subject to UV radiation. This breaks the siloxane linkage of the silane to the silicon oxide surface thereby exposing the silicon oxide surface. Backfilling can then be used to create a bifunctional surface.

(III) Direct Writing Using SAMs as Resists in Electron Beam Lithography and Scanning Tunneling Microscopy: Similar to the technique of using a SAM as a resist in photolithography, a homogeneous SAM is formed on a surface, and an electron beam is scanned across the surface to remove the surfactant molecules in the desired pattern. The source of the electron beams can either be a conventional device used in electronics microfabrication or the head of a scanning tunneling microscope (STM) that provides a well localized source of low energy electrons. Because of the resolution of the beam, this technique can write patterns on the nanometer scale, which can then be backfilled with a second silane to create a bifunctional surface.

(IV) Direct Writing Using Atomic Force Microscopy (AFM): These methods use the tip of a scanning probe microscope (AFM or STM) to pattern the surface (see Xu, S.; Miller, S.; Laibinis, P. E.; Liu, G. Y. Langmuir 1999, 15, 7244-7251; Mirkin, C. Inorganic Chemistry 2000, 39, 2258-2272; Piner, R. D.; Zhu, J.; x, F.; Hong, S. H.; Mirkin, C. A. Science 1999, 283, 661-663; Piner, R. D.; Mirkin, C. A. Langmuir 1997, 13, 6864-6868; Li, Y.; Maynor, B. W.; Liu, J. J. Am. Chem. Soc. 2001, 123, 2105-2106; Mirkin, C. A.; Hong, S. H.; Demers, L. Chemphyschem 2001, 2, 37-39; Amro, N. A.; Xu, S.; Liu, G. Y. Langmuir 2000, 16, 3006-3009; and Hang, S. H.; Mirkin, C. A. Science 2000, 288, 1808-1811). For example, the tip can be used to displace by either physically nanoshaving (AFM) or electrochemically etching (STM) molecules of an already deposited SAM to create a pattern. Alternatively, in dipped pen nano-lithography, the tip is used to transfer a self-assembling surfactant onto the surface thereby creating the pattern.

(V) Backfilling Technique: In this technique, the nano-island domains are put down first (see Kumar, N.; Steiner, C.; Maldarelli, C.; Couzis, A. Langmuir 2001, 17, 7789-7797). They are assembled by using self-assembling surfactants which, when they adsorb (for periods of deposition shorter than those necessary to achieve complete coverage), phase separate into condensed islands and a background gaseous phase. Following the formation of the condensed island domains, the matrix is deposited by exposing the substrate to a solution of the second self-assembling surfactant.

(VI) Mixed Adsorption: In the mixed adsorption technique, the substrate is dipped into a solution containing the surfactant that will make up both the island and matrix phases and these phase separate upon adsorption to form the desired pattern (see Fan, F.; Couzis, A.; Maldarelli, C. Langmuir (in press) 2002). The central challenge with this technique is to insure that the segregation takes place. This requires an understanding of the factors which control the phase separation as opposed to those which promote uniform mixing.

All of these methods can be used to fabricate nanometer size domains on a flat substrate that contain one chemical functionality relative to a surrounding matrix. However flat substrates are not very useful for larger scale production of nano-particles, which requires a large surface area per volume for the templating surfaces. The present invention, on the other hand, can, in addition to flat substrates, use carrier particles with diameters in the range of 1 to 1000 μm. To pattern these types of curved surfaces only approaches (V) and (VI), previously developed by applicants, are applicable.

An outline of the process based on the use of a flat substrate substantially covered by the templating nano-sectors (nano-wells, nano-islands and nano-domains) defined by the inert matrix (inert sectors) is given below. Such surfaces are used to simplify developing the technology and templating process on a laboratory scale. However, one skilled in the art would recognize that, in using curved surface substrates, the basic steps remain conceptually the same, though the mechanisms and mechanical equipment change.

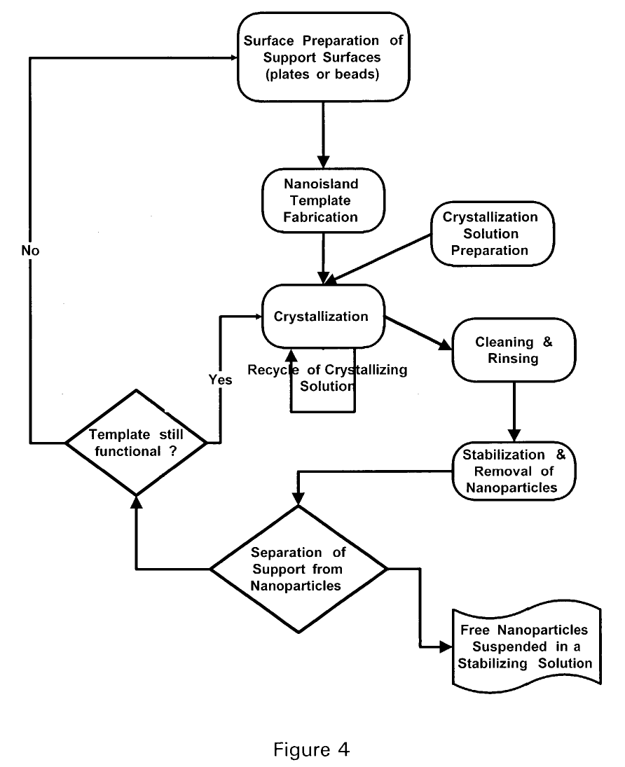

The unique crystallization process of the invention is schematically described in FIG. 4. The process is a combination of eight basic steps (though some may be combined), which do not necessarily require separate vessels.

1) Preparation of the solid substrate surface: First a suitable carrier material is chosen. The choice depends on the compounds that create the matrix and the templating domains, as they have to be able to covalently (or chemically) bind to the surface. Silicon oxide (silicon wafers with a native oxide layer or glass slides) is used in the examples. However other materials with compatible surface modification chemical pathways can also be used, such as apatite and hydroxyapatite particles and plates using phosphate based self-assembling surfactants, polar surface polymerics using silane based self-assembling surfactants, and alumina (and other metal oxide surfaces) using carboxylic acid self-assembling surfactants. Water-soluble carriers may also be used. The surface should be smooth and even (at the level of the domain features that are prepared herein) and free of all contamination, specifically, organic materials that adhere to the surface. The preparation of the solid substrate surface can be performed in various ways and is specific to the substrate material selected. It is advantageous to choose surfaces or structures that can be easily handled and moved from vessel to vessel, such as on plates on racks, or small particles that can be fluidized or suspended by agitation in a liquid and easily separated from the solution by differences in density between the liquid solution and the carrier particles.

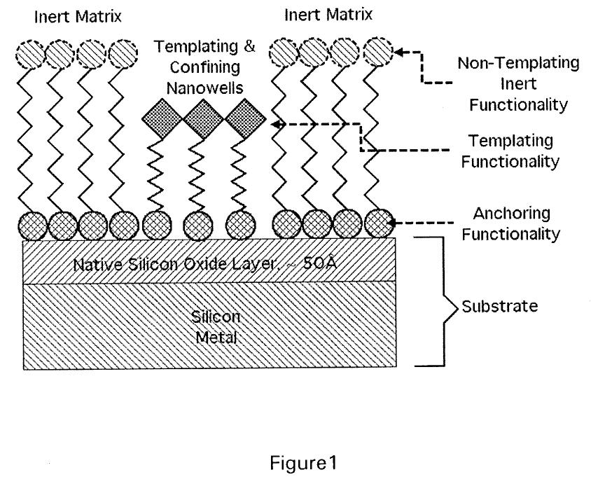

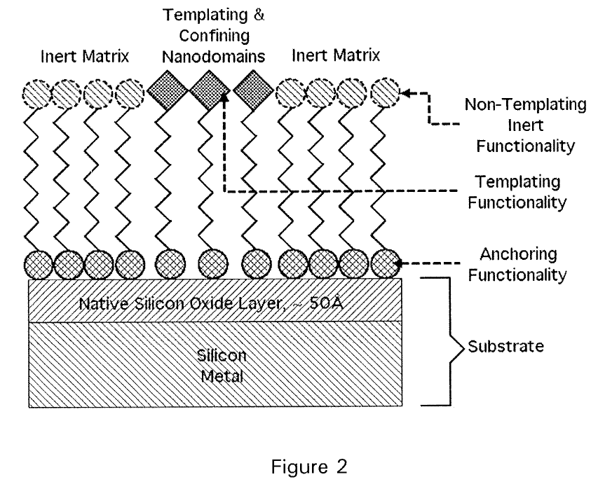

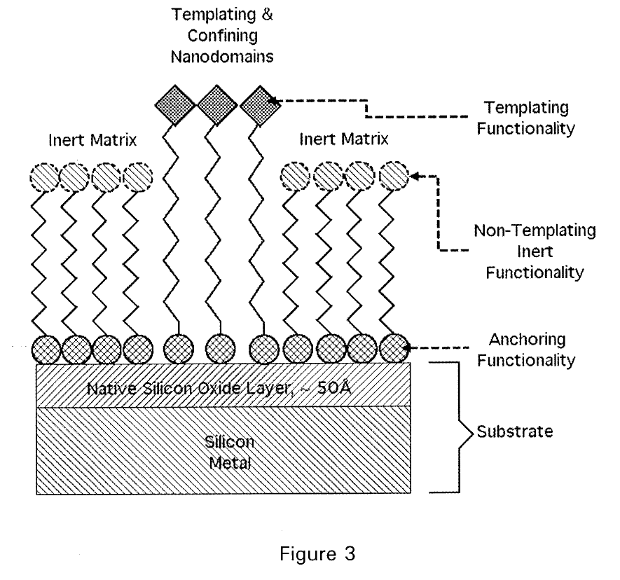

2) Fabrication of the nano-patterned surface template on the surface of the substrate: The cleaned surface is exposed to compounds that create the templating nano-sectors. The surface of the substrate is substantially covered with nano-sectors bound by inert sectors. The nano-sectors are discrete and relatively uniform, have a diameter of from 5 to 1000 nanometers, preferably between 10 and 400 nanometers, and comprise surface functional groups (including but not limited to, amino, hydroxyl, carboxyl, acid, and charged groups such as sulfate, sulphonate or sacrosinate) that promote nucleation of crystals. For crystallization of a particular compound, the functional groups are selected based on their ability to reduce the interfacial surface tension against the growing nuclei of that compound. For example, for crystallization of vanillin (see Examples 4 and 5), which possesses a hydroxyl group, suitable functional groups include amino and acid groups. These functional groups hydrogen-bond with the hydroxyl functionality present on the vanillin, thereby reducing the interfacial tension, and allowing templated crystallization to occur. The nano-sectors preferably constitute from about 5% to about 60% of the area of the substrate surface. The inert sectors comprise a surface inert to promotion of nucleation thereon. Relative to the surface of the inert sectors, the nano-sectors may be i) below the surface (which we refer to as nano-wells, see FIG. 1), ii) coplanar with the surface (which we refer to as nano-domains, see FIG. 2) or iii) above the surface (which we refer to as nano-islands, see FIG. 3). These two processes (the formation of the nano-sized features and the creation of the templates within them) can be performed in one step or in several steps, all depending on the specific application and the necessary surface functionalization. The size and density of the nano-feature is controlled by adjusting the composition and concentration of the treating solutions, and depends on the substrate and the way chosen to prepare the nano-sized features. Details of the formation conditions and the controlling mechanism are reported in the literature (see Mirkin, C. A.; Hong, S. H.; Demers, L. Chemphyschem 2001, 2, 37-39; Kumar, N.; Steiner, C.; Maldarelli, C.; Couzis, A. Langmuir 2001, 17, 7789-7797; Fan, F.; Couzis, A.; Maldarelli, C. Langmuir (in press) 2002; and Biebuyck; Hans A., L.; B., N. IBM Journal of Research & Development 1997, 41).

3) Preparation of the crystallizing solution: As in any crystallization, a suitably supersaturated solution is prepared. As the crystallization is carried out with low supersaturation, the solute to be crystallized may have to be constantly added to the solution to maintain the supersaturation. This is standard crystallization technology.

4) Crystallization: The prepared surfaces are immersed in a batch into a crystallizer containing the crystallizing solution for a predetermined time of from a few minutes to tens of hours. It is mandatory that the concentration of the solution be below the self-nucleating limit. If desired, the nucleation and growth step can be separated using different concentrations. The growth period and the rate of growth depend on the desired size in the direction perpendicular to the surface, and have to be adjusted to prevent the lateral growth of the crystal out of the island. It is preferred that the concentration (or supersaturation) of the solute is kept constant over the whole reactor volume to assure uniform size of all crystals. In a batch process all crystals will be the same size, even if this is not constant concentration, however, constant concentration gives reproducibility from batch to batch. Inorganic and organic compounds may be crystallized from organic or aqueous solutions. Suitable, non-limiting examples of compounds to crystallize include ionic crystals, such as calcium carbonate, hydroxyapatite, barium sulfate and calcium sulfide, and molecular (organic) crystals, such as vanillin, alanine, glycine, taxol, diazepam, atropine, cyclosporins and antibiotics.

5) Washing and post-treating: The crystallizing solution is removed from the plates (or the carrier particles). The plates (or carrier particles) are rinsed with an anti-solvent and any particles not attached to the surface are washed away. This ensures that the final dispersion of the nano-particles will be free of larger crystals or crystallized nano-particles formed by agglomeration of crystalline particles that either fell off the surface or grew from nuclei formed in the solution itself.

If desired, the rinsed nano-particles can then be treated or coated in any desirable way. For example, for pharmaceuticals there have been many proposals for coating particles with target directing compounds or other coatings. One can also coat with a stabilizing compound. Such coatings may include, but are not limited to: (i) polyethylene glycol terminated surfactants or polymers that stabilize the nano-particles and enhance their transport rates through biological membranes; (ii) charged polymers or surfactants (amine or acid terminated) to electrostatically stabilize the nano-particles; (iii) wetting agents (pluronics, sulfonates, sulfates, laurates sarcoccinates) that increase the nano-particle compatibility for mixing into various materials as fillers. After further cleaning, the plates with the particles still attached can then be dried in an inert atmosphere, if desired. The final use is based on the nano-particles remaining attached to the carrier substrate.

6) Removal from the surface: For many cases the nano-particles have to be removed from the carrier surface. The removal can be achieved by mechanical, physical or chemical means, including, but not limited to, sonication, changes of pH, impinging jets, vibration, gas stream, etc. The removal of the particles from the supporting surface can be carried in a variety of media:

(a) Removal of the nano-particles into a stabilizing solution: Once the nano-particles are removed from the surface, they would tend to agglomerate unless they are stabilized. One embodiment of the present invention involves removing the nano-particles into a solution containing a stabilizer, to prevent or slow the agglomeration. For aqueous environments, polyethylene glycol based surfactants or polymers may be used to stabilize the nano-particles.

(b) Removal of the nano-particles into a liquid suspension of solid particles that adsorb the nano-particles: In some cases, the nano-particles are used freestanding, such as for delivery of hard-to-dissolve drugs by, for example, direct infusion of a nano dispersion. However, in the majority of end uses, the nano-particles are mixed into a solid matrix. For this purpose they have to be uniformly dispersed into the matrix. As the concentration of the nano-particles in the matrix is generally low, one can use microsized particles (1 to 200 microns, preferably less than 10 microns) of the final solid matrix, which should be porous, and suspend them in water or any other suitable liquid, and release the nano-particles directly into an agitated dispersion of these microsized particles. Alternatively, one can use a fibrous solid material for the same purpose. The suspension of the solid matrix particle with the nano-particles attached can then be filtered and further processed. This is a unique advantage of the present invention.

(c) The same result as in (b) can also be achieved by ejecting the nano-particles into a gas stream, and arresting them in a fluidized suspension of the solid matrix particles. In both (b) and (c), in order to achieve a good dispersion, it is desirable to use as small particles of the solid matrix as possible, as the size of the carrier particles determines the scale of non-uniformity.

7) The carrier surface is removed from the suspension: For plates this is simple, as one can lift them out of the vessel. For small particles this can easily be done by elutriation of the product suspension or by settling of the carrier particles.

8) The support particles or plates are recycled: In most cases the carrier surfaces from step 7 are still useable or can be directly fed back to step 4. After some time they have to be fed back to step 1 or 2.

In one embodiment, four vessels are used for efficiency and vessel utilization in semi-continuous large-scale production. For a small production rate, the number of vessels can easily be reduced or the particle carrier plates can be appropriately coated before use with the templating SAM. The plates provide a smaller surface-to-volume ratio and can be used in a batch scheme where the plates can be transported from vessel to vessel. This simpler method is useful for the exploratory phase and development stages.

It is the process of providing these uniform particles by the combination of the different steps which is the basis of the subject invention. The use of the self-assembling monolayers as templates for directing crystal habit as well as the creation of controlled size nano-islands on a surface has been previously developed.

The process of the present invention uniquely allows nano-particles to be prepared by crystallization, while simultaneously controlling their size and habit. Such uniformly-sized nano-particles have not been produced by crystallization until now and the availability of such uniformly-sized nano-particles offers new and valuable applications to nano-technology in many different areas.

Limiting the crystallization to nucleation sites in the nano-templates, growing the crystals attached to the nano-templates, and washing all crystals formed in the solution (either by breaking off of a small crystal or by self-nucleation) allows for a very close control of particle size, especially if one uses a slow growth rate and uniform residence time for each growing crystal. The crystals can be then transferred into a stabilizing solution, the formulation of which depends on the end use. The use of nano-templates (either nano-wells, nano-islands, or nano-domains) for forming uniformly sized nano-particles is an essential element of the subject invention.

Description of Large Scale Implementations of the Invention

In this section, several methods for carrying out a larger scale industrial process are described. These are given as examples only and the process shown could be modified to meet particular needs:

a) A process based on racks of plates.

This is very similar to the Examples described below, with the exception that large plates with multiple plates mounted on a carrier rack are used.

b) Use of small particles as carrier surfaces.

The productivity of nano-particles per unit surface is small due to very small size of the nano-particles. For a particle size of 50 nanometers and a surface coverage of 30%, a batch of one gram would require a surface area of about 65 m². A one cubic meter vessel filled with 50 micron carrier particles suspended in a liquid fluidized bed with a loading density of 0.8 would provide a surface area of 36,000 m², allowing for a production of about 550 grams of 50 nanometer particles.

The surface available in a given volume of such a suspension is inversely proportional to the carrier particle size. The productivity per batch is proportional to the area available as well as to the dimension of the nano-particles perpendicular to the surface. The size of the carrier particle has to be significantly larger than the nano-particles, such that the surface is essentially flat. The carrier particles may be, but are not limited to, glass beads, beads of a pharmaceutically acceptable drug excipient and polylactic acid beads.

There are many ways in which the present invention can be implemented. Here we give one example in which the carrier particles are either fluidized, or kept suspended in the treating as well as crystallizing solutions by some form of agitation (either mechanical agitation or by circulation of liquid). Separation of the carrier particles from the liquid is achieved by utilizing the gravity difference between the carrier particles and the liquid, either by stopping or slowing the agitation or by using a centrifuge or filter.

In a preferred embodiment, carrier particles above 20 microns in size are used, as they can easily be separated from the liquid.

For many suitable carrier surfaces, such as silicon and glass, such particles are readily available. For the carrier particles, a uniform size (or nano-size distribution) is not necessary. For most other carrier surfaces, such particles are readily made by available technology. In FIG. 4, a schematic flowchart shows how such a process can be implemented. In FIG. 4, the individual boxes represent large vessels (or reactors) equipped with the necessary cooling or heating and with an agitation device which keeps the small particles suspended. In the preferred implementation, this agitation and suspension is achieved either by pumping the solution through a stationary fluid bed of the small carrier particle or by providing mild mechanical agitation. The latter allows use of standard crystallizers, or reactors available in most crystallization facilities. The top of the vessel is preferentially wider, such that a particle-free solution can be drawn off and recycled to the bottom of the vessel to provide the flow necessary for fluidization. When it is desired to separate the particles from the liquid, the agitation, or the velocity of the flow can be reduced or stopped, and the solids can be removed through a suitable exit pipe as a dense suspension to another vessel. This is true for each of the vessels. A gas or vapor fluidized bed can also be substituted in one of the steps, should drying or high temperature treatment be desirable.

The process is preferably operated as a semi-continuous or batchwise continuous process, in which each of the vessels is loaded with the solids transferred from the previous step and then treated as described in the examples. A true continuous process is more complicated, as a stirred tank crystallizer has a non-uniform (Poisson) residence time distribution, whereas the treatment step as well as crystallization requires a uniform residence time for each carrier particle.

For a sufficiently large production capacity, a continuous process can be designed by having several crystallizers and treatment vessels in series, as a series of stirred tanks approaches plug flow.

Each of the individual vessels can be designed to meet the specific needs of a given step for a specific process. However, the equipment can be designed to be flexible enough to be suitable for a variety of processes. Particle size can be varied by changing both process conditions as well as crystallization time.

Special emphasis has to be given to the way the nano-crystals are removed from the surface of the carrier particles. The present invention provides unique advantages, as the removal can be adapted for different end uses. For example, if the nano-particles are intended to be used as drugs there are several options. The Examples below are again only given to illustrate the capabilities of the method.

a) Delivery by oral, injection or intravenous infusion: The present invention may be used to prepare nano-particles comprising a pharmaceutically acceptable drug or medicament. The nano-crystals may be pharmaceuticals having limited solubility, in particular those having a solubility of less than 10 mg/ml.

These may be used for oral, injection or intravenous infusion purposes. For this, a dilute suspension is used, the suspension being more dilute for use in intravenous infusion than for injection. The storability of the liquid dispersion of drug nano-particles depends on the surface stabilizing agent used. In most cases it is of limited duration (months not years). For intravenous administration, the single crystalline nano-crystals may be placed inline to an intravenous feed system, dissolved in the intravenous fluid in the feed system and administered to a mammal in need thereof.

Such a dispersion can be obtained in many ways from a suspension of the carrier particles by dislodging the particles by sonication, jet impingement, change of pH or other means. As the carrier particles are larger, the nano-crystals can be elutriated with the liquid from the carrier particle. As the amount of nano-particles per unit volume of carrier particles is quite small, one might have to repeat this step several times with the same batch of stabilizing solution.

As the long-term stability of stabilized dispersion of nano-particles is limited, it is sometimes advisable to store or even ship the nano-particles while still attached to the carrier surface, and dislodge the nano-particles into the stabilizing liquid shortly before use.

b) Use dispersed in a solid matrix: In many applications the nano-particles are used dispersed in a solid excipient. Examples include pills, capsules, skin patches of drugs, aerosols of particles forced into the skin or inhaled, implants, etc. Typical excipients include, but are not limited to, cellulose, sorbitol and various sugars. For all such cases, proper dispersion of a stabilized nano-particle dispersion was previously quite difficult to achieve. An advantage of the present invention is that this dispersion may be performed simultaneously with the dislodging step. For this purpose properly sized fine particles, fibers (or other forms) of the solid excipient can be used dispersed in either a liquid or a gas and mixed with carrier particles while exposed to the dislodging method. Proper agitation has to be provided to ensure uniform deposition in the solid matrix. Separation of the carrier particles from the product or the solid matrix particles is quite easy if the two have significantly different particle sizes. To achieve a good dispersion and a reasonable loading, the excipient particles have to be small. If the size of the excipient particles is too large, they do not have sufficient surface to accept the nano-particles and the latter will coat them with a shell, thereby defeating the purpose. Excipient particles are typically in the micron range (though the present invention is not limited to this constraint) which can still be separated from a liquid or gas dispersion.

An advantage of the present invention is that a stabilizer may not be needed in order to give substantially better dispersions than may be obtained using previously known methods. This also has the advantage of avoiding the difficulty mentioned above that in a single batch the dislodging leads to a very dilute dispersion. Here any desired concentration factor can be used, provided the particle size of the excipient and the method are adjusted properly. Even a relatively dilute dispersion of a small particle size (2 micron) excipient is sufficient for catching all dislodged nano-crystals. Because the particles are large enough to be centrifuged, the narrow particles can be removed from the dispersion in a concentrated form.

Further processing of the excipient has to be fitted to the application and standard technology is available for this purpose.

Those examples serve as illustration only, as many other applications are obvious to those skilled in the art.

Direct Use of the Carrier Particles

For a number of uses, direct use of the nano-particles while still attached to the carrier may be of great advantage. Suitable, but non-limiting examples include:

1) Direct growth of nano-crystals in defined nano-domains on a surface on micron sized carrier particles. One possible uses of this composition, when the nano-crystalline materials are pharmaceuticals, is in the preparation of intravenous solutions at the point of use. This can be done by releasing the nano-crystalline pharmaceutical into the solution (for example, by sonication) with removal of the carrier particles, or by placing the composition inline with the intravenous feed so that the nano-crystalline pharmaceutical can be dissolved into the feed.

2) Direct growth of the nano-particles on small carrier particles of solid matrix in which the crystalline nano-particles are integrated. In this case, the carrier particle and the nano-crystals are used as one specific product.

3) Use of porous carrier particles that are useful for the final product.

For Example 2 above, and many other cases, it is sometimes preferable to use porous carrier particles with pore diameters reasonably large compared to the desired nano-particles. If these porous carrier particles are kept small enough, they offer practically no diffusional resistance for either surface templating preparation or crystallization, provided the timescale of these processes is kept small compared to the timescale of diffusion inside the particle. Suitable examples of applicable carriers, include, but are not limited to, spray dried particles of 10 to 50 microns in diameter, having porosities of about 0.25 to about 0.75. Materials useful for the preparation of these carriers include sugars, such as dextrose, fructose, maltose, cellulosics, silica gel, syloids and sylox, xanthan gums, calcium phosphates and combinations thereof.

To provide a better understanding of the invention, five examples are provided, each illustrating a specific feature of the process. While the process provides better control of size distribution in the nano range than other known crystallizing process, simultaneous control of particle size in the nano range coupled with: control of crystal habit, reactive crystallization, control of polymorph, operation in an organic solvent, and use of spherical beads has not been achieved by any other prior process.

### EXAMPLE 1

This example demonstrates the crystallization of an inorganic salt, vaterite, while simultaneously controlling its crystal habit and the particle size in the nanometer range. Vaterite is the least favored polymorph of calcium carbonate, meaning that its crystallization under homogenous nucleation conditions is highly improbable. Homogeneous nucleation processes of calcium carbonate typically yield calcite. Vaterite, the hexagonal form of calcium carbonate, has the best mechanical strength, making it a viable option for filler applications for filled polymers where high strength is required. In a recent publication, it has been shown that surfaces that ionically bind either of the two counterions, such as amino or carboxyl terminated surfaces, will selectively template vaterite over any other calcium carbonate polymorph. This occurs because the templating surface reduces the interfacial work penalty associated with the formation of a nucleus, and thus reduces the overall free energy required for the nucleation of the templated species. In separate articles (see Fan, F.; Couzis, A.; Maldarelli, C. Langmuir (in press) 2002; and Fan, F.; Chi, C.; Green, D. A.; Meenan, P.; Maldarelli, C. M.; Couzis, A. Langmuir 2001, Submitted for Publication), fabrication methods have been shown that can produce surfaces consisting of nano-islands of one chemical functionality surrounded by a matrix of a second different chemical functionality. The island size and density are controllable and can be adjusted according to requirements. The controlling schemes are discussed in the research articles. When the islands are amino-terminated, then we have two-dimensional confined areas that act as nucleation centers for crystallization. When crystallization of calcium carbonate is carried on these nano-patterned surfaces, vaterite nano-crystals with a very tight size distribution are produced.

In this example, the experimental conditions required to reproduce these vaterite nano-crystals are:

Step 1) Support Preparation: Polished silicon wafers are scored and cut into 2 cm×2 cm strips. The strips are then cleaned by sonicating in a mixture of Nochromix® and 98% sulfuric acid for about 30 minutes, followed by successive water rinsing (10 times). The cleaned substrates are then stored under water. They are dried in a stream of dry nitrogen just before use (if desirable, the nitrogen can be heated). This approach results in a highly hydrophilic surface, which is required for the subsequent steps of the surface preparation. In a continuous process, drying of the carrier surface is not required.

Step 2) Nano-Island Template Fabrication: The amino-terminated islands in a sea of methyl are prepared using a co-adsorption and phase separation approach that has been previously developed, as noted earlier. A solution of octadecyltrichlorosilane (OTS) and p-aminophenyltrimethoxysilane (APhMS) in chloroform is prepared. The molar ratio of OTS to APhMS is 3:1 and the total solution concentration is 2 mM. This solution is prepared by mixing 0.0582 gm of OTS and 0.011 gm of APhMS in 100 ml of chloroform. After the 2 mM solution is prepared, the silicon wafers strips are immersed in the solution for 2 hours at room temperature (23±2° C.). Upon removal of the surface from the solution and examination under an atomic force microscope, islands of amine termination in a sea of methyl termination are identified with an average size of 30 nm±5 nm. The size of the islands can be increased if the ratio of APhMS:OTS is increased. The density of the islands is controlled by the total concentration of the solution.

Step 3) Preparation of the Crystallizing Solution: The crystallizing solution of CaCO₃ is prepared according to the procedure of Kitano (see Kitano, Y. Applied Crystallization 1962, 35, 1980-1985). Carbon dioxide gas is bubbled through a stirred aqueous suspension of CaCO₃ (2 gm calcite per liter) for approximately 3 hr to produce a supersaturated solution according to the following reaction:

CaCO₃(s)+CO₂(g)+H₂O(l)→Ca²⁺(aq)+2HCO₃⁻(aq)

The suspension is then filtered (0.22 μm, Millipore membrane). The pH of the resulting solution is 5.8 to 6.0. The concentration of calcium ion in the solution is determined by EDTA (ethylenediaminetetraacetic) substitution titration at pH>10, with Eriochrome black T as an indicator. The supersaturated solution is stocked in a flask and diluted to the desired concentration (4.5 mM) before the crystallization experiment.

Step 4) Crystallization: A solution containing 4.5 mM of CaCO₃ is first prepared as described in section 3. This concentration is below the metastable limit where there is very little self-nucleation in the solution, but high enough to nucleate in the islands of amino-terminated surface. These amine-terminated surfaces in the island serve as a template for crystallization of the vaterite. A template of a different molecular structure would preferentially nucleate another polymorph. The islands confine the space where nucleation and growth of the vaterite crystals can occur.

The size of the crystal in the direction normal to the surface depends on the time of exposure as well as the Ca²⁺concentration. In this experiment the exposure time is 1 hour and the Ca²⁺is 4.5 mM. Growing too large in the longitudinal dimension will cause spreading of the crystal outside the island. In this example the longitudinal growth is limited to 10 nm to achieve better uniformity. The average particle size achieved was 30±5 nm (95% of all particles fall in this range), with no particles above 50 nm.

Step 5) Rinsing: After the desired particle size (height) is reached, the surface is rinsed with a 30% solution of alcohol in water. The rinsing removes all calcite particles that may have aggregated and agglomerated to a larger size or may have a different crystal form as they were not nucleated into a template.

Step 6) Stabilization: The crystals that remain are protected from aggregation by being bound to the surface. After rinsing, the host particles (along with the nano-particles on their surfaces) are immersed in a solution consisting of a 30% solution of alcohol in water with the addition of 0.1 mM sodium laureate. The vaterite nano-crystals are then removed from the surface directly by sonication into this stabilizing solution. This can also be done by other methods, such as by changing the pH or exposing the stable solution to high velocity jets. The sodium laureate is adsorbed on the crystal surface and sterically prevents the crystals from agglomeration.

### EXAMPLE 2

In this example, in a reactive crystallization scheme, cadmium sulfide crystals are formed by reacting two solutes:

Step 1) Support Preparation: As in the previous example.

Step 2) Nano-Island Template Fabrication: As in the previous example.

Step 3) Preparation of Crystallizing Solution: In this reactive crystallization scheme, two solutions are prepared, one 10 mN aqueous solution of sodium sulfide (Na₂S) and one 10 mM aqueous solution of cadmium chloride (CdCL₂).

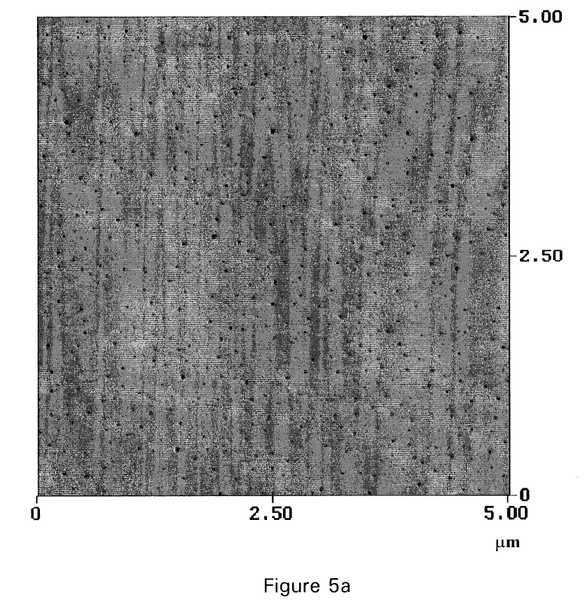

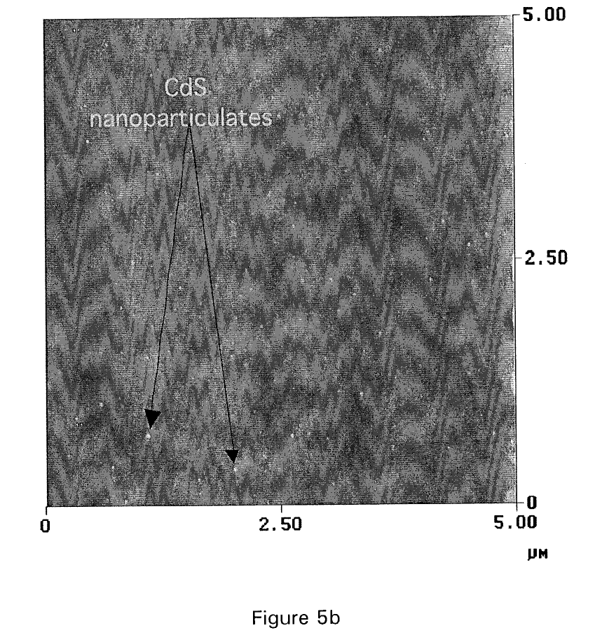

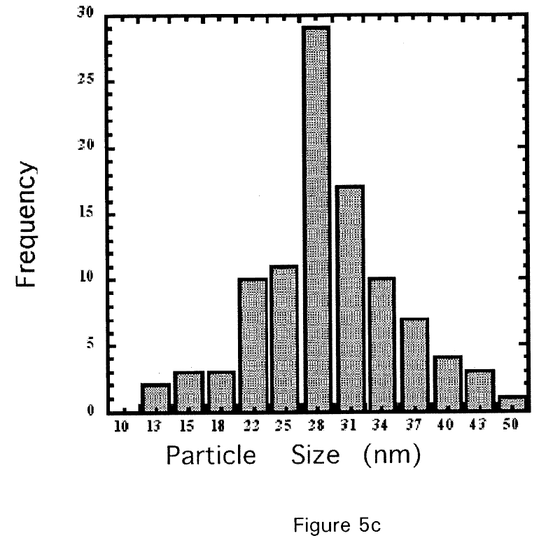

Step 4) Nano-Particle Crystallization: The surface is immersed in the aqueous solution of Na₂S (sodium sulfide) (10 mM). After 1 hour exposure, the surface is removed and rinsed and immediately immersed in the 10 mM aqueous solution of CdCl₂ (cadmium chloride). After 1 hour of contact, the substrate is removed and imaged under an atomic force microscope. The resulting particles have an average size of 28 nm±5 nm. Atomic force microscope images of the amino terminated nano-islands before and after reactive crystallization of CdS, along with a schematic of the particle size distribution of the resulting CdS nano-crystals are shown in FIGS. 5a, 5b and 5c, respectively. This example is of special interest, as most of the other methods for creating nano-particles by crystallization are either not suitable or much more difficult to use for reactive crystallization.

Step 5) Rinsing: The rinsing solution is a solution of ethanol in water.

Step 6) Stabilization: The stabilizing solution is again a water-alcohol solution with sodium laureate. The stages themselves are identical to Example 1, except the growth step is carried out in two separate steps and in a batchwise continuous process or a particulate process in two separate vessels.

### EXAMPLE 3

This example demonstrates the ability of the subject invention to preferably crystallize the L or D form of the chiral amino acid alanine. To achieve this preferred selectivity, surfaces were constructed consisting of islands of bromine termination in a sea of methyl termination.

Step 1) Support Preparation: As in Example 1.

Step 2) Nano-Island Template Fabrication: A solution of octadecyltrichlorosilane (OTS) and 3-bromo-propyl-trichlorosilane (BrPS) in chloroform is prepared. This solution is prepared by mixing in 100 ml of chloroform 0.0582 gm of OTS and 0.0256 gm of BrPS. The molar ratio of OTS to BrPS is 3:1 and the total solution concentration is 2 mM. After the 2 mM solution is prepared, the silicon wafers strips are immersed in the solution for 2 hours at room temperature (23±2° C.). Upon removal of the surface from the solution and examination under an atomic force microscope, islands of bromine termination in a sea of methyl termination are identified. This approach results in islands with an average size of 35±7 nm. The resulting surface is then immersed in a 1 mM solution of the L or D-cystine (0.024 gm of cystine (L or D) in 100 ml of DMF) in DMF. After two hours, the surface is removed, rinsed with ethanol and hexadecane and dried in a nitrogen stream.

Step 3) Preparation of Crystallizing Solution: Alanine supersaturated solutions are prepared by dissolving 30 g racemic alanine in 100 mL of Millipore prepared water at 35° C. Upon cooling to 25° C., the resulting solution is 25% supersaturated.

Step 4) Nano-Particle Crystallization: The alanine supersaturated solution is then brought into contact with the chiral surface for approximately 1 hour at room temperature. When the surface used is the L-cystine we selectively crystallize the L-form of alanine, and when the D-cystine surface is used, the D-form of alanine is selectively crystallized.

Step 5) Rinsing: The rinsing solution is ethanol.

Step 6) Stabilization: The stabilizing solution is again a water-alcohol solution with sodium laureate.

### EXAMPLE 4

In this example, vanillin nano-particles are formed on two types of nano-patterned surfaces. The first type of surface consists of aminopropyltrimethoxysilane (APS) nano-wells bound by a matrix of octadecyltrichlorosilane (OTS). This surface is referred to as APS/OTS. The second type of surface consists of hydrolyzed cyanoundecyltrimethoxysilane (CUTMS) coplanar nano-domains bound by a matrix of octadecylytrichlorosilane. This surface is referred to as CUTMS/OTS.

Step 1) Support Preparation: As in the previous examples

Step 2) Nano-well Template Fabrication: The amino terminated nano-wells were formed by depositing from a mixture of APS and OTS (with a composition ratio of 1:3) from a chloroform solution with a total concentration of 0.2 mM and 0.02% water. The CUTMS/OTS coplanar nano-domains were deposited from a CUTMS and OTS solution with a composition ratio of 1:3 from chloroform solution with a total concentration of 0.5 mM and 0.02% water. Before modifying the CUTMS monolayer, the substrates were annealed at 150° C. for about 2 hours. The monolayer was not stable for the above-mentioned reaction conditions unless it was annealed. The CUTMS islands were then oxidized to —COOH using a hydrolysis procedure using a 50:50 (v/v) solution mixture of 15% Hydrochloric acid and deionised water at 75° C. Atomic force microscopy confirmed the formation of ˜100 nm nano-islands. The formation of carbonyl islands after the oxidation of the cyano terminal group was verified using internal reflection infrared spectroscopy.

Step 3) Preparation of the Crystallizing Solution: A 10% w/w solution (2 gm/20 ml of solvent) of vanillin in chloroforn was prepared.

Step 4) Nano-Particle Crystallization: The substrate, as prepared in steps 1 and 2 was directly put into the supersaturated vanillin solution, as prepared in step 3, in for 2 hours. AFM was used to image particles on surfaces. On the 100 nm amino terminated island surfaces vanillin platelets with ˜100 nm diameters were observed. The thickness of plate is 2 to 3 nm in AFM height image. The friction of the OTS matrix is lower than that of the vanillin particles due to the interaction of the silicon nitride tip of the AFM with the vanillin.

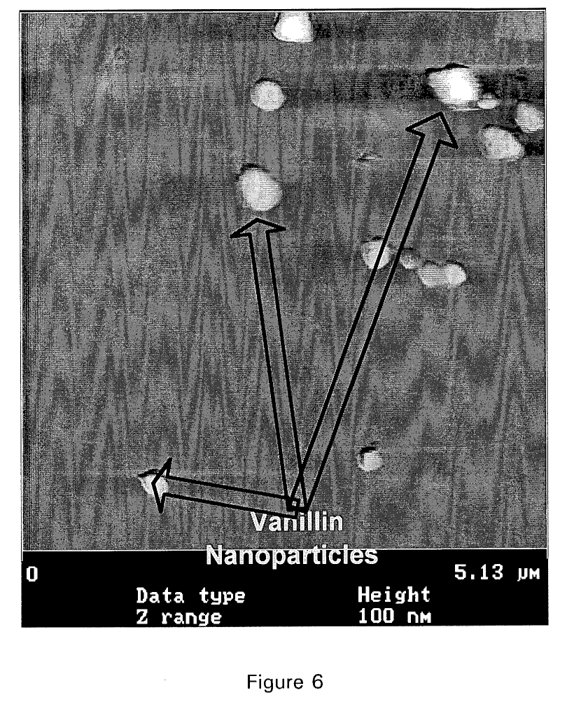

Vanillin nano-particles were also grown on the oxidized CUTMS nano-islands. After preparing the substrate according to the methods described in step 3 the substrate was immersed in supersaturated vanillin solution in chloroform for 2 hours. Following removal and rinsing the AFM height image exhibited island structures with ˜100 nm diameters and 2 to 3 nm heights (FIG. 6). The friction images appear the same size nano-islands with high friction. Those results suggest that vanillin crystals grow on COOH surfaces.

### EXAMPLE 5

Vanillin nano-particles were formed on island templates of self-assembled monolayers formed on micron sized glass beads. As in Example 4, two types of domains were investigated, an amino terminated nano-well and a acid terminated nano-island both in a sea of inert methyl termination.

Step 1) Support Preparation: 300 micrometer glass beads were used as the substrate for the templated crystallization process. The glass beads were purchased from Aldrich-Sigma Chemicals, and were cleaned by sonicating in a mixture of Nochromix ® and 98% sulfuric acid for about 30 minutes, followed by successive water rinsing (10 times). The cleaned glass beads were then stored under water, filtered and dried in a stream of dry nitrogen just before use (if desirable, the nitrogen can be heated). This approach results in a highly hydrophilic surface, which is required for the subsequent steps of the surface preparation.

Step 2) Template fabrication: The procedure is outlined in the Example 4, with the addition of brisk mixing in order to prevent the glass beads from settling.

Step 3) Crystallizing Solution Preparation: The procedure is outlined in the Example 4. Nano-islands and nano-wells formed were in the ˜100 μm range as characterized by atomic force microscopy.

Step 4) Nano-Particle Crystallization: The substrate glass beads, as prepared in steps 1 and 2, were directly placed into the supersaturated vanillin solution, as prepared in step 3, in for 2 hours. AFM was used to image particles on surfaces. Brisk mixing prevented the glass beads from settling during the crystallization process. On the 100 nm amino terminated island surfaces vanillin platelets with roughly 100 nm diameters were observed. The thickness of plate is ˜3 nm in AFM height image. Very similar samples were also prepared when the COOH terminated islands were used. Both sets of results obtained using glass beads mirror nicely the vanillin resulting from crystallization on flat surfaces.

The process as shown in the Examples is illustrative of the basic steps which may be used to practice the invention. These are cost-effective and realize the unique advantage of the invention. However, it will be understood that many variations of the processes may be made without departing from the scope of the invention.

We claim:

1. A process for generating single crystalline nano-crystals comprising:
(A) forming a substrate, the surface of which is substantially covered with nano-sectors bound by inert sectors, wherein:
a. the nano-sectors are discrete and relatively uniform, have a diameter from 5 to 1000 nanometers, and comprise surface functional groups that promote nucleation of crystals; and
b. the inert sectors comprise a surface inert to the promotion of nucleation thereon and, relative to the surface of the inert sectors, the surface of the nano-sectors are:
i. below the surface (nano-wells),
ii. above the surface (nano-islands), or
iii. coplanar with the surface (nano-domains);
(B) contacting said substrate surface with a solution containing a crystallizable substance;
(C) forming crystalline nuclei within or upon said nano-sectors; and
(D) growing single crystalline nano-crystals on said nuclei, such that the particle size of said single crystalline nano-crystals is controlled by the size of the nano-sectors, said single crystalline nano-crystals being reversibly attached to the surface of said nano-sectors during crystallization.

2. The process according to claim 1 wherein the substrate comprises a carrier having a flat or curved reactive surface.

3. The process according to claim 2 wherein the carrier is a spherical particle.

4. The process according to claim 2 wherein the carrier is a glass fiber, a glass bead or a silicon plate.

5. The process according to claim 2 wherein the carrier is a bead of a pharmaceutically acceptable drug excipient.

6. The process according to claim 2 wherein the carrier is porous.

7. The process according to claim 2 wherein the diameter of said carrier is between 1 and 1000 microns.

8. The process according to claim 2 wherein the carrier is water-soluble.

9. The process according to claim 3 wherein the carrier is a polylactic acid bead.

10. The process according to claim 1 wherein the size of said uniform nano-sectors is between 10 and 400 nanometers.

11. The process according to claim 1 wherein said nano-sectors constitute from about 5% to about 60% of the area of the substrate surface.

12. The process according to claim 1 wherein the surface functional groups on the nano-sectors are amino, hydroxyl or carboxyl.

13. The process according to claim 1 wherein the single crystalline nano-crystals are inorganic or organic compounds crystallized from an organic or an aqueous solution.

14. The process according to claim 1 wherein the single crystalline nano-crystals are inorganic compounds produced by reactive crystallization by contacting the substrate with a first solute and thereafter contacting the substrate with one or more solutes.

15. The process according to claim 1 wherein the single crystalline nano-crystals are organic stereoisomers crystallized from a racemic mixture, wherein the orientation of said stereoisomers matches the orientation of the surface functional groups.

16. The process according to claim 1 wherein the single crystalline nano-crystals are pharmaceuticals having a solubility in water of less than 10 mg/ml.

17. A process for generating single crystalline nano-crystals comprising the steps of:
(A) forming a substrate, the surface of which is substantially covered with nano-sectors bound by inert sectors, wherein:
a. the nano-sectors are discrete and relatively uniform, have a diameter from 5 to 1000 nanometers, and comprise surface functional groups that promote nucleation of crystals; and
b. the inert sectors comprise a surface inert to the promotion of nucleation thereon and, relative to the surface of the inert sectors, the surface of the nano-sectors are:
i. below the surface (nano-wells),
ii. above the surface (nano-islands), or
iii. coplanar with the surface (nano-domains);
(B) contacting said substrate with a solution containing a crystallizable substance;
(C) forming crystalline nuclei within or upon said nano-sectors;
(D) growing single crystalline nano-crystals on said nuclei, such that the particle size of the single crystalline nano-crystals is controlled by the size of the nano-sectors, said single crystalline nano-crystals being reversibly attached to the surface of said nano-sectors during crystallization;
(E) removing said solution from the substrate containing the single crystalline nano-crystals attached to the nano-sectors;
(F) washing said single crystalline nano-crystals;
(G) optionally coating said single crystalline nano-crystals with a coating agent; and
(H) optionally drying said single crystalline nano-crystals within or upon said nano-sectors.

18. The process according claim 17 wherein the coating agent is a surfactant, a polymeric stabilizer, a permeable barrier, a dissolvable barrier, or a target directing compound.

19. The process according to claim 17 further comprising the steps of:
(I) optionally, storing said single crystalline nano-crystals within or upon said nano-sectors;
(J) optionally, shipping the single crystalline nano-crystals within or upon said nano-sectors; and
(K) removing the single crystalline nano-crystals from the substrate surface of said nano-sectors prior to use.

20. The process according to claim 19 wherein the single crystalline nano-crystals are removed from the substrate surface by mechanical, physical or chemical means.

21. The process according to claim 19 wherein the single crystalline nano-crystals are removed from the substrate surface by sonication, jet impingement, vibration or changing the pH.

22. The process according to claim 19 further comprising removing the single crystalline nano-crystals from the substrate using a stream of gas.

23. The process according to claim 1 wherein the surface of the substrate is porous.

24. A substrate composition comprising a surface which is substantially covered with nano-sectors and inert sectors, wherein:
(A) the nano-sectors are discrete and relatively uniform, have a diameter from 5 to 1000 nanometers, and comprise surface functional groups that promote nucleation of crystals; and
(B) the inert sectors comprise a surface inert to the promotion of nucleation thereon and, relative to the surface of the inert sectors, the surface of the nano-sectors are:
i. below the surface (nano-wells),
ii. above the surface (nano-islands), or
iii. coplanar with the surface (nano-domains);
(C) single crystalline nano-crystals within or upon said nano-sectors, wherein the single crystalline nano-crystals are reversibly attached to the surface of said nano-sectors and have a particle size which correlates to the diameter of the nano-sectors.

25. The substrate composition of claim 24 wherein the diameter of the nano-sectors is between 5 and 400 nanometers.

26. The substrate composition of claim 24 wherein the nano-sectors constitute from about 5% to about 60% of the area of the surface of the substrate composition.

27. The substrate composition of claim 24 wherein the single crystalline nano-crystals are inorganic compounds produced by reactive crystallization by contacting the substrate composition with a first solute and thereafter contacting the substrate composition with one or more solutes.

28. The substrate composition of claim 24 wherein the surface functional groups are amino, hydroxyl or carboxyl.

29. The substrate composition of claim 24 wherein the single crystalline nano-crystals are inorganic compounds formed by reactive crystallization.

30. The substrate composition of claim 24 wherein the single crystalline nano-crystals are organic stereoisomers, the orientation of which matches the orientation of the surface functional group.

31. The substrate composition of claim 24 wherein the single crystalline nano-crystals are inorganic or organic compounds crystallized from an organic or aqueous solution.

32. The substrate composition of claim 24 wherein the substrate composition is a carrier.

33. The substrate composition of claim 24 wherein the substrate composition is porous.

34. The substrate composition of claim 24 wherein the substrate composition comprises a carrier having a surface reactive flat or curved surface.

35. The substrate composition of claim 32 wherein the carrier is glass fibers, glass beads or silicon plates.

36. The substrate composition of claim 32 wherein the carrier is a bead of a pharmaceutically acceptable drug excipient.

37. The substrate composition of claim 32 wherein said carrier has a diameter of between 1 and 1000 microns.

38. The substrate composition of claim 32 wherein said carrier is spherical.

39. The substrate composition of claim 32 wherein the carrier is water-soluble.

40. Single crystalline nano-crystals prepared by forming a substrate, the surface of which is substantially covered with nano-sectors bound by inert sectors, wherein:
(A) the nano-sectors are discrete and relatively uniform, have a diameter from 5 to 1000 nanometers, and comprise surface functional groups that promote nucleation of crystals; and
(B) the inert sectors comprise a surface inert to the promotion of nucleation thereon and, relative to the surface of the inert sectors, the surface of the nano-sectors are:
i. below the surface (nano-wells);
ii. above the surface (nano-islands); or
iii. coplanar with the surface (nano-domains);
(C) contacting said substrate with a solution containing a crystallizable substance;
(D) forming crystalline nuclei within or upon said nano-sectors;
(E) growing single crystalline nano-crystals on said nuclei, such that the particle size of said single crystalline nano-crystals is controlled by the size of the nano-sectors, said nano-crystals being reversibly attached to the surface of said nano-sectors during crystallization; and
(F) separating the single crystalline nano-crystals from said substrate.

41. The single crystalline nano-crystals of claim 40 wherein the nano-crystals are inorganic or organic compounds crystallized from an organic or aqueous solution.

42. The single crystalline nano-crystals of claim 40 wherein the nano-crystals are an inorganic compound formed by reactive crystallization.

43. The single crystalline nano-crystals of claim 40 further comprising the steps of: washing the substrate and recycling the washed substrate to the nano-crystal generating process of claim 1.

44. The single crystalline nano-crystals of claim 40 wherein the nano-crystals are organic stereoisomers, the orientation of which matches the orientation of the surface functional group.

45. The single crystalline nano-crystals of claim 40 wherein the nano-crystals are pharmaceuticals having a solubility in water of less than 10 mg/ml.

46. The process according to claim 1 further comprising the steps of:
(E) suspending the single crystalline nano-crystals containing substrate of claim 1 in an aqueous stabilizing solution;
(F) removing the single crystalline nano-crystals from the nano-sectors by mechanical, physical or chemical means; and
(G) removing the substrate from the resulting aqueous suspension of single crystalline nano-crystals.

47. The process according to claim 46 further comprising the steps of washing and recycling the substrate to repeat the nano-crystal generating process of claim 1.

48. The process according to claim 1 further comprising the steps of:
(E) coating the single crystalline nano-crystals containing substrate of claim 1 with an aqueous stabilizing surfactant solution;
(F) suspending the coated single crystalline nano-crystals in a liquid organic medium;
(G) removing the single crystalline nano-crystals from the nano-sectors by mechanical, physical or chemical means; and
(H) removing the substrate from the resulting organic emulsion of the single crystalline nano-crystals.

49. The process according to claim 48 further comprising the steps of washing and recycling the substrate to repeat the nano-crystal generating process of claim 1.

50. The process according to claim 3 further comprising the steps of:
(E) drying the single crystalline nano-crystals containing substrate of claim 3 with a carrier gas to create a fluidized bed;
(F) removing the nano-crystals from the nano-sectors by sonication of the fluid bed;
(G) elutriating the nano-crystals from the fluid bed by the carrier gas; and
(H) passing the carrier gas containing the elutriated nano-crystals through another fluid bed containing porous media to produce a porous solid with embedded nano-crystals.

51. The process according to claim 50 further comprising the steps of washing and recycling the substrate to repeat the nano-crystal generating process of claim 1.

52. The process according to claim 1 further comprising the steps of:
(E) drying the single crystalline nano-crystals containing substrate;
(F) removing the single crystalline nano-crystals from the nano-sectors by sonication in a carrier gas;
(G) elutriating the nano-crystals from the substrate with the carrier gas; and
(H) passing the carrier gas containing the elutriated nano-crystals through a fluid bed containing porous media to produce a porous solid with embedded nano-crystals.

53. The process for producing single crystalline nano-crystals according to claim 52 further comprising the steps of washing and recycling the substrate to repeat the nano-crystal generating process of claim 1.

54. A method of treating a mammal with an effective amount of a pharmaceutical of claim 45 which comprises: placing the single-crystal nano-crystals of said pharmaceutical inline to an intravenous feed system; dissolving said nano-crystals in the intravenous fluid in said feed system; and administering the intravenous fluid containing the pharmaceutical to said mammal.

55. A method of treating a mammal which comprises: orally administering to said mammal an effective amount of the single-crystal nano-crystals of the pharmaceutical of claim 45.
